(19) United States
(12) Patent Application Publication
(10) Pub. No.: US 2003/0142484 A1
(43) Pub. Date: Jul. 31, 2003

(54) Backplane

(75) Inventors: Jeffrey W. Hanson, Redondo Beach, CA (US); James R. Moore, Irvine, CA (US); Matthew Kusz, Minneapolis, MN (US)

Correspondence Address: FOGG AND ASSOCIATES, LLC, P.O. BOX 581339, MINNEAPOLIS, MN, 55458-1339, US

(73) Assignee: ADC DSL Systems, Inc.

(21) Appl. No.: 10/059,646

(22) Filed: Jan. 29, 2002

(51) Int. Cl. H05K 7/14; H05K 7/18

(52) U.S. Cl. 361/796

(57) ABSTRACT

A single backplane for a housing is provided. A plurality of sockets is disposed on a first side of the backplane, where each of the sockets is adapted to receive a repeater. A connector is disposed on a second side of the backplane and is electrically connected to each of the sockets by conductive traces disposed within the backplane. The connector is adapted to plug into a mating connector for connecting each of the plurality of sockets to input and output transmission lines.

### TECHNICAL FIELD

The present invention relates generally to the field of interconnecting devices for electronics and, in particular, to backplanes.

### BACKGROUND

Signals are often transferred over long distances through transmission lines. For example, telecommunications signals are usually transferred over long distances from a central office to a subscriber location and vice versa through transmission lines. In many instances, the signal may be too weak by the time it reaches its destination to be useful. Consequently, electronic circuits, e.g., repeaters, are deployed after a length of transmission line (incoming line) for detecting, cleaning up, and amplifying a weak signal for transmission through another length of transmission line (outgoing line). Repeaters are often deployed in housings, such as environmentally protected housings, located above and below ground.

Several repeaters are usually located in a single housing. The repeaters are usually plugged into sockets within the housing that are wired to the incoming and outgoing lines. Typically, each of the sockets is wired to the incoming and outgoing lines by wire wrapping each of a large number of pins of the socket to corresponding wires on the incoming and outgoing lines. For example, many 819-type repeater housings employ multiple circuit boards (or backplanes). Each backplane has several sockets mounted on a surface of the backplane so that pins of each of the sockets protrude from an opposite surface of the backplane. Each of these pins are usually connected to the incoming and outgoing lines by wire wrapping. However, wire wrapping is usually a time-consuming and costly process. Moreover, some servicing procedures, e.g., replacing one or more sockets or circuit boards, repairing dysfunctional wire-wrap connections, etc., involve unwrapping and rewrapping several wire-wrap connections. This often increases the servicing time and thus the cost of servicing. Additionally, multiple backplanes add to the complexity of many 819-type repeater housings, which increases the time and cost for manufacturing many 819-type repeater housings.

For the reasons stated above, and for other reasons stated below which will become apparent to those skilled in the art upon reading and understanding the present specification, there is a need in the art for reducing the number of wire-wrap connections within a repeater housing and for reducing the number of backplanes within repeater housings.

### SUMMARY

The above-mentioned problems with wire wrapping and multiple backplanes within repeater housings and other problems are addressed by embodiments of the present invention and will be understood by reading and studying the following specification. Embodiments of the present invention provide a single backplane for reducing the number of wire-wrap connections. This facilitates reductions in manufacturing and/or servicing costs associated with wire wrapping. Embodiments of the present invention further provide repeater housings, such as 819-type repeater housings, having a single backplane. This reduces the time and cost of manufacturing many repeater housings.

More particularly, in one embodiment, a single backplane for a repeater housing is provided. A plurality of sockets is disposed on a first side of the backplane, where each of the sockets is adapted to receive a repeater. A connector is disposed on a second side of the backplane and is electrically connected to each of the sockets by conductive traces disposed within the backplane. The connector is adapted to plug into a mating connector for connecting each of the plurality of sockets to input and output transmission lines.

In another embodiment, a housing for containing a plurality repeaters is provided. The housing includes a plurality of slots, where each of the plurality of slots is adapted to respectively receive each of the plurality repeaters therein. Also included is a single backplane having a plurality of sockets disposed on a first side thereof. Each of the plurality of sockets is respectively aligned with each of the plurality of slots for respectively receiving each of the plurality of repeaters therein. A connector is disposed on a second side of the single backplane and is electrically connected to each of the plurality of sockets by conductive traces disposed within the single backplane. The connector is adapted to plug into a mating connector for connecting each of the plurality of sockets to input and output transmission lines.

In another embodiment, a method for processing a plurality of signals is provided. The method includes receiving the plurality signals at a connector via a mating connector plugged into the connector. The connector is disposed on a first side of a backplane, and the backplane is disposed within an 819-type repeater housing. Also included is respectively conveying each of the plurality of signals to each of a plurality of sockets using conductive traces disposed within the backplane. Each of the plurality of sockets is disposed on a second side of the backplane. The method includes respectively conveying each of the plurality of signals from each of the plurality of sockets to each of a plurality of repeaters respectively located in each of the plurality of sockets. Moreover, the method includes respectively processing each of the plurality of signals at each of the plurality of repeaters.

In another embodiment, a single backplane for an optical network unit is provided. A plurality of sockets is disposed on a first side of the backplane, where each of the sockets is adapted to receive a circuit card having an optical-to-electrical signal converter. A connector is disposed on a second side of the backplane and is electrically connected to each of the sockets by conductive traces disposed within the backplane. The connector is adapted to plug into a mating connector for connecting each of the plurality of sockets to input and output transmission lines.

Other embodiments are described and claimed.

### BRIEF DESCRIPTION OF THE DRAWINGS

FIG. 1 is a bottom view of an embodiment of a backplane according to the teachings of the present invention.

FIG. 2 is a top view of the backplane of FIG. 1.

FIG. 3 illustrates an embodiment of a repeater according to the teachings of the present invention.

FIG. 4 is an exploded perspective view of an embodiment of a housing according to the teachings of the present invention.

### DETAILED DESCRIPTION

In the following detailed description, reference is made to the accompanying drawings that form a part hereof, and in which is shown by way of illustration specific illustrative embodiments in which the invention may be practiced. These embodiments are described in sufficient detail to enable those skilled in the art to practice the invention, and it is to be understood that other embodiments may be utilized and that logical, mechanical and electrical changes may be made without departing from the spirit and scope of the present invention. The following detailed description is, therefore, not to be taken in a limiting sense.

Embodiments of the present invention provide a single backplane for housings, such as 819-type repeater housings, e.g., an ENCASER 819 commercially available from ADC Telecommunications of Eden Prairie, Minn., electronics housings, or the like. Multiple sockets adapted to receive circuit cards, such as repeaters, e.g., HDSL, HDSL2, ISDN, etc., are disposed on one side of the backplane. Instead of the sockets being wire wrapped to input and output transmission lines, the sockets are connected to electrically conductive traces disposed within the backplane. The electrically conductive traces are connected to one or more connectors disposed on an opposite side of the backplane. These connectors plug into mating connectors that are prewired to the input and output transmission lines. Therefore, the sockets are connected to the input and output transmission lines by plugging the mating connector into the connector instead of wire wrapping the sockets to the input and output transmission lines.

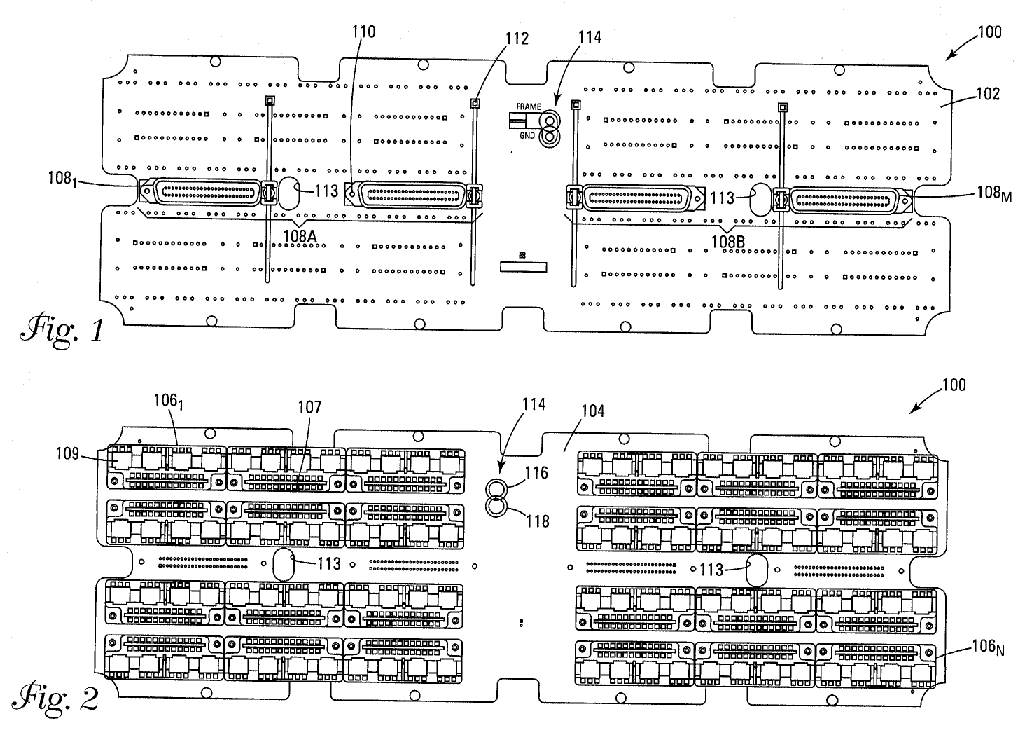

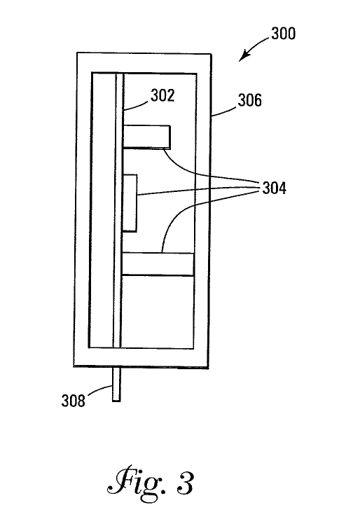

FIGS. 1 and 2 are respectively bottom and top views of an embodiment of a backplane 100 according to the teachings of the present invention. Backplane 100 has surfaces 102 and 104. Several sockets 106₁ to 106_{N} are disposed on surface 104. Each of sockets 106 is electrically connected to backplane 100 and includes a slot 107 adapted to receive a repeater. In one embodiment, each of sockets 106 includes a number of protectors 109, such as gas-tube protectors, for protecting the repeater against power surges induced by lightening, power cables, or the like.

A number of connectors 108₁ to 108_{M} are disposed on surface 102 and are electrically connected to sockets 106, e.g., using conductive traces, such as copper traces, disposed within or on backplane 100. Each of connectors 108 is adapted to plug into a mating connector that is connected to a transmission line, such as a telecommunications line. Electrically connecting connectors 108 to sockets 106 using conductive traces in or on backplane 100 and plugging connectors 108 into mating connectors to connect each of sockets 106 to a transmission line replaces the common approach of using wire wraps to connect pins of sockets 106 to the transmission line.

In one embodiment, some of connectors 108 plug into mating connectors connected to an input transmission line, and other of connectors 108 plug into mating connectors connected to an output transmission line. In another embodiment, e.g., for an 819-type repeater housing, connectors 108 include pairs (e.g., input and output) of connectors 108. For example, connector-pair 108_{A} and connector-pair 108_{B}, as shown in FIG. 1, each include an input and output connector. The input connector of each of connector-pairs 108_{A} and 108_{B} plugs into a mating connector connected to an input transmission line. The output connector of each of connector-pairs 108_{A} and 108_{B} plugs into a mating connector connected to an output transmission line. In another embodiment, connector-pairs 108_{A} and 108B are connected to each of sockets 106 by conductive traces disposed within or on backplane 100.

In some embodiments, each of sockets 106 has two pairs (e.g., each pair including a RING and a TIP) of input pins and two pairs (e.g., each pair including a RING and a TIP) of output pins. In one embodiment, one of the two pairs of input pins is connected to a pair of corresponding pins of the input connector of connector-pair 108_{A} by conductive traces disposed within backplane 100, and the other of the two pairs of input pins is connected to a pair of corresponding pins of the input connector of connector-pair 108_{B} by the conductive traces. Moreover, one of the two pairs of output pins is connected to a pair of corresponding pins of the output connector of connector-pair 108_{A} by the conductive traces, and the other of the two pairs of output pins is connected to a pair of corresponding pins of the output connector of connector-pair 108_{B} by the conductive traces. The term “pin” should not be limited to a specific physical design, but is intended to represent any electrical interconnection.

Protectors 109, in one embodiment, tap into input lines (e.g., RING-TIP input pairs) before the repeater and into output lines (e.g., RING-TIP output pairs) after the repeater and interconnect the input and output lines to a ground. During normal operation, protector 109 is open so that no current passes through protector 109, but rather passes to or from the repeater, bypassing protector 109. In the event of a power surge in the input and/or output transmission line, the relatively high current causes protector 109 to close. This creates a short circuit to the ground so that the high current flows to the ground instead of into the repeater.

In one embodiment, a mating connector is secured to one of connectors 108 by passing a screw through the mating connector and threading the screw into an aperture 110 in connector 108. In another embodiment, a tie 112 is disposed on each connector 108 for further securing each connector 108 to the respective mating connector by wrapping around the respective mating connector. In various embodiments, connectors 108 are available from Amp, a TYCO International Ltd. Company, Inc., Stoney Creek, Alberta, Canada, as part number 554758-1. In some embodiments, apertures 113 pass through backplane 100 for accommodating a clamping device for clamping the repeaters within a housing, such as an 819-type repeater housing.

In one embodiment, backplane 100 has a ground connector 114. Ground connector 114, in some embodiments, includes internally threaded fasteners 116 and 118 pressed into apertures in backplane 100. In these embodiments, each conductor of a two-conductor ground cable is attached to a lug. Each lug is secured to ground connector 114 at surface 102 by passing, for example, a screw through the lug and threading the screw into one of threaded fasteners 116 and 118.

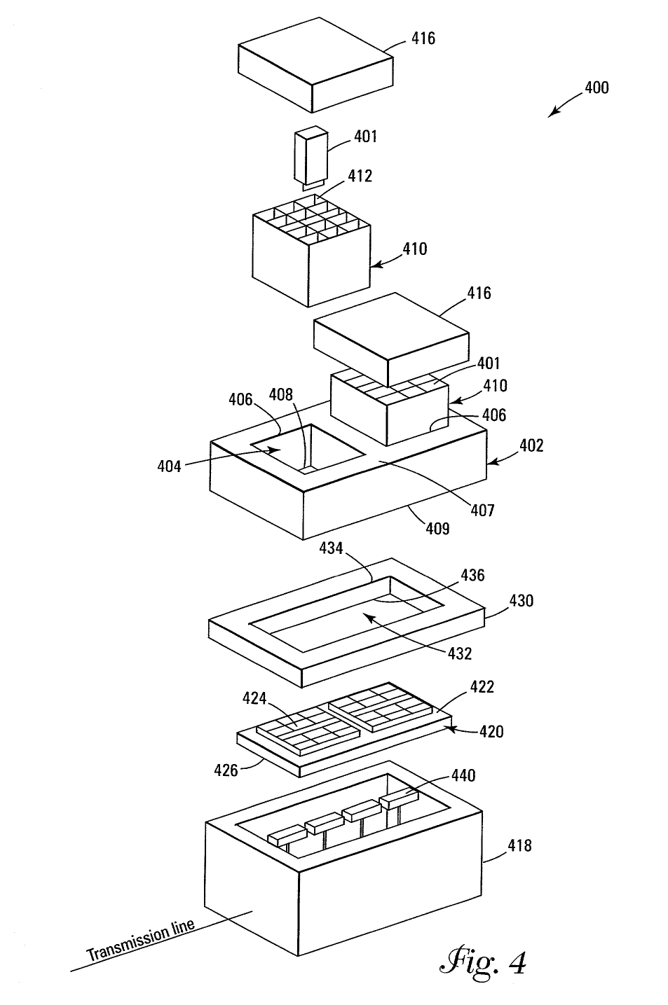

In one embodiment, each of sockets 106 is adapted to receive an embodiment of a repeater 300, shown in FIG. 3, in slot 107. Repeater 300 includes a circuit board 302 having one or more circuit components 304. In some embodiments, a case 306 encloses circuit board 302. Repeater 300 includes plug 308 electrically connected to circuit board 302. Plug 308 is received by slot 107 of one sockets 106 for electrically connecting circuit board 302 to backplane 100 and thus to connectors 108 that are connectable to a transmission line via mating connectors.

In one embodiment, the input connector of connector-pair 108_{A} receives a number of first input signals from an input transmission line via a mating connector plugged into the input connector of connector-pair 108_{A}, and the input connector of connector-pair 108_{B} receives a number of second input signals from an input transmission line via a mating connector plugged into the input connector of connector-pair 108_{B}. Each of the first input signals (e.g., a RING and a TIP) is respectively conveyed to each of sockets 106 by conductive traces disposed within backplane 100. In addition, each of the second input signals (e.g., a RING and a TIP) is respectively conveyed to each of sockets 106 by the conductive traces. The first and second input signals received at each of sockets 106 from the input connector of connector-pair 108_{A} and the input connector of connector-pair 108_{B} are conveyed from each of sockets 106 into each of a number of repeaters (e.g., repeater 300) respectively inserted into each of sockets 106. Each repeater processes, e.g., boosts and amplifies, the first and second input signals and outputs the processed first and second signals to the socket 106 into which the repeater is inserted. Processed first signals are conveyed from each of sockets 106 to the output connector of connector-pair 108_{A} by the conductive traces. Processed second signals are also conveyed from each of sockets 106 to the output connector of connector-pair 108_{B} by the conductive traces. The processed first and second signals are respectively output to output transmission lines via mating connectors plugged into the output connector of each of connector-pairs 108_{A} and 108_{B}.

FIG. 4 shows an embodiment of a housing 400 for containing a multitude of repeaters 401 according to the teachings of the present invention. In various embodiments, each of repeaters 401 is as described for repeater 300 of FIG. 3. In one embodiment, housing 400 includes a shell 402 having compartments 404. In another embodiment, compartments 404 each have apertures 406 and 408 that provide openings into compartments 404 and that respectively lie in planes of surfaces 407 and 409 of shell 402. In one embodiment, housing 400 includes a shell 430 that is selectively secured to surface 409 of shell 402, by fasteners, such as bolts, screws, or the like. Shell 430 includes a compartment 432 having, in one embodiment, apertures 434 and 436, where aperture 434 lies in approximately the plane of surface 409 of shell 402. In one embodiment, covers 416 respectively selectively close each of apertures 406 of shell 402, while cover 418 selectively closes aperture 436 of shell 430.

Each of compartments 404, in one embodiment, includes a case 410 that resides between surfaces 407 and 409 of shell 402 for confining each of repeaters 401 to a distinct location within housing 400. Case 410 has a multitude of slots 412. Each of slots 412 is adapted to respectively contain each of the multitude of repeaters 401.

A single backplane 420, which in one embodiment is as described for backplane 100 of FIGS. 1 and 2, is located in housing 400, e.g., in compartment 432 of shell 430. In one embodiment, a surface 422 of backplane 420 lies in approximately the plane of surface 436. Backplane 420 includes a multitude of sockets 424 that are disposed on surface 422 of backplane 420. In one embodiment, sockets 424 are as described for sockets 106 of backplane 100 of FIG. 2. Sockets 424 are connected to connectors, such as connectors 108 of FIG. 1, that are disposed on surface 426 of backplane 420 via conductive traces, for example. In one embodiment, mating connectors, e.g., mating connectors 440, are secured within cover 418. When cover 418 closes aperture 436 of shell 430, mating connectors 440 respectively align with and plug into the connectors, e.g., connectors 108 of FIG. 1, that are disposed on surface 426 of backplane 420 to connect sockets 424 to incoming and outgoing transmission lines.

Cases 410 are inserted into compartments 404 so that each of slots 412 respectively align with each of sockets 424 of backplane 420. Each of repeaters 401 is respectively inserted into each of slots 412 and respectively plugs into each of sockets 424. In one embodiment, housing 400 is an 819-type repeater housing, such as the ENCASER 819 commercially available from ADC Telecommunications of Eden Prairie, Minn.

### CONCLUSION

Embodiments of the present invention have been described. The embodiments provide a backplane for 819-type repeater housings, e.g., an ENCASER 819 commercially available from ADC Telecommunications of Eden Prairie, Minn. Multiple sockets adapted to receive repeaters are disposed on one side of the backplane. Conductive traces disposed within the backplane interconnect the sockets to one or more connectors disposed on an opposite side of the backplane. These connectors are adapted to plug into mating connectors that are prewired to input and output transmission lines. This enables the sockets to be connected to the input and output transmission lines by plugging the mating connector into the connector instead of wire wrapping pins of the sockets to the input and output transmission lines, thereby facilitating reductions in manufacturing and/or servicing costs associated with wire wrapping. Embodiments of the present invention also provide repeater housings that have a single backplane rather than multiple backplanes. This reduces the time and cost of manufacturing many repeater housings.

Although specific embodiments have been illustrated and described in this specification, it will be appreciated by those of ordinary skill in the art that any arrangement that is calculated to achieve the same purpose may be substituted for the specific embodiment shown. This application is intended to cover any adaptations or variations of the present invention. For example, the present invention is not limited to the housing 400 of FIG. 4. Instead, a backplane, such as backplane 100 or 400, can be mounted in a compartment of a single-compartment housing so that slots disposed within the compartment align with sockets on the backplane. Moreover, the slots may or may not be disposed in a case, such as case 410. Alternatively, the backplane can be disposed in a housing having several compartments, such as compartments 404, each containing a case, such as case 410, so that slots disposed within each case align with sockets of the backplane. In addition, the present invention is not limited to repeaters or housings for repeaters. Instead, it is appreciated that circuit cards other than repeaters can be inserted into slots 107 of backplane 100. For example, in some embodiments, circuit cards including any outside plant electronics, such as alarm circuits, switching circuits, optical-to-electrical signal converters, line cards, or the like are inserted into slots 107 of backplane 100. In some embodiments, housing 400 or the like houses an optical network unit (ONU). In other embodiments, backplane 100 can include optical-to-electrical signal converters.

What is claimed is:

1. A single backplane for a repeater housing comprising:
a plurality of sockets disposed on a first side of the backplane, each of the plurality of sockets adapted to receive a repeater; and
a connector disposed on a second side of the backplane and electrically connected to each of the plurality of sockets by conductive traces disposed within the backplane, wherein the connector is adapted to plug into a mating connector for connecting each of the sockets to input and output transmission lines.

2. The backplane of claim 1, wherein the backplane is disposed in a shell.

3. The backplane of claim 1, wherein each of the plurality of sockets comprises a slot for receiving a plug of the repeater.

4. The backplane of claim 1, wherein the connector comprises an input and Output connector.

5. The backplane of claim 1, further comprising a tie disposed on the connector for wrapping around the mating connector to secure the mating connector to the connector when the mating connector plugs into the connector.

6. A single backplane for an 819-type repeater housing comprising:
a plurality of sockets disposed on a first side of the backplane, each of the plurality of sockets adapted to receive a repeater; and
a connector disposed on a second side of the backplane and electrically connected to each of the plurality of sockets by conductive traces disposed within the backplane, wherein the connector is adapted to plug into a mating connector for connecting each of the sockets to input and output transmission lines.

7. The backplane of claim 6, wherein each of the plurality of sockets comprises a protector for protecting the repeater received therein against power surges.

8. The backplane of claim 7, wherein the protector comprises a plurality of protectors.

9. The backplane of claim 7, wherein the protector comprises a gas tube.

10. The backplane of claim 6, wherein the backplane is disposed in a shell.

11. The backplane of claim 6, wherein each of the plurality of sockets comprises a slot for receiving a plug of the repeater.

12. The backplane of claim 6, wherein the connector comprises an input and output connector.

13. The backplane of claim 6, further comprising a tie disposed on the connector for wrapping around the mating connector to secure the mating connector to the connector when the mating connector plugs into the connector.

14. A single backplane for a repeater housing comprising:
a plurality of sockets disposed on a first side of the backplane, each of the plurality of sockets having a slot adapted to receive a repeater;
first and second input connectors disposed on a second side of the backplane, the first and second input connectors electrically connected to each of the plurality of sockets by conductive traces disposed within the backplane, wherein the first and second input connectors are adapted to respectively plug into first and second input mating connectors for connecting each of the plurality of sockets to a transmission line for delivering signals to each of the sockets; and
first and second output connectors disposed on the second side of the backplane, the first and second output connectors electrically connected to each of the plurality of sockets by the conductive traces disposed within the backplane, wherein the first and second output connectors are adapted to respectively plug into first and second output mating connectors for connecting each of the plurality of sockets to a transmission line for receiving signals from each of the sockets.

15. The backplane of claim 14, wherein the backplane is disposed in a shell.

16. The backplane of claim 14, further comprising a tie disposed on each of the first and second input connectors and on each of the first and second output connectors for wrapping around each of the first and second input mating connectors and each of the first and second output mating connectors to respectively secure each of the first and second input mating connectors to each of the first and second input connectors when each of the first and second input mating connectors respectively plugs into each of the first and second input connectors and to respectively secure each of the first and second output mating connectors to each of the first and second output connectors when each of the first and second output mating connectors respectively plugs into each of the first and second output connectors.

17. A single backplane for an 819-type repeater housing comprising:
a plurality of sockets disposed on a first side of the backplane, each of the plurality of sockets having a slot adapted to receive a repeater;
first and second input connectors disposed on a second side of the backplane, the first and second input connectors electrically connected to each of the plurality of sockets by conductive traces disposed within the backplane, wherein the first and second input connectors are adapted to plug into first and second input mating connectors for connecting each of the plurality of sockets to a transmission line for delivering signals to each of the sockets; and
first and second output connectors disposed on the second side of the backplane, the first and second output connectors electrically connected to each of the plurality of sockets by the conductive traces disposed within the backplane, wherein the first and second output connectors are adapted to plug into first and second output mating connectors for connecting each of the plurality of sockets to a transmission line for receiving signals from each of the sockets.

18. The backplane of claim 17, wherein each of the plurality of sockets comprises a protector for protecting the repeater received therein against power surges.

19. The backplane of claim 17, wherein the backplane is disposed in a shell.

20. The backplane of claim 17, further comprising a tie disposed on each of the first and second input connectors and on each of the first and second output connectors for wrapping around each of the first and second input mating connectors and each of the first and second output mating connectors to respectively secure each of the first and second input mating connectors to each of the first and second input connectors when each of the first and second input mating connectors respectively plugs into each of the first and second input connectors and to respectively secure each of the first and second output mating connectors to each of the first and second output connectors when each of the first and second output mating connectors respectively plugs into each of the first and second output connectors.

21. A housing for containing a plurality of repeaters comprising:
a plurality of slots, each of the plurality of slots adapted to respectively receive each of the plurality of repeaters therein;
a single backplane having a plurality of sockets disposed on a first side thereof, each of the plurality of sockets respectively aligned with each of the plurality of slots for respectively receiving each of the plurality of repeaters therein;
the single backplane having a connector disposed on a second side thereof, wherein the connector is electrically connected to each of the plurality of sockets by conductive traces disposed within the single backplane; and
wherein the connector is adapted to plug into a mating connector for connecting each of the sockets to input and output transmission lines.

22. The housing of claim 21, wherein each of the plurality of sockets comprises a protector for respectively protecting each of the plurality of repeaters received therein against power surges.

23. The housing of claim 22, wherein the protector comprises a gas tube.

24. The housing of claim 21, wherein the connector comprises an input and output connector.

25. The housing of claim 21, wherein each of the plurality of sockets comprises a slot for respectively receiving a plug of each of the plurality repeaters.

26. The housing of claim 21, wherein the single backplane is disposed within a compartment of the housing.

27. A housing for containing a plurality of circuit cards comprising:
a case having a plurality of slots, each of the plurality of slots adapted to respectively receive each of the plurality of circuit cards therein;
a single backplane having a plurality of sockets disposed on a first side thereof, each of the plurality of sockets respectively aligned with each of the slots of the case for respectively receiving each of the plurality of circuit cards therein;
first and second input connectors disposed on a second side of the single backplane, the first and second input connectors electrically connected to each of the plurality of sockets by conductive traces disposed within the single backplane, wherein the first and second input connectors are adapted to plug into first and second input mating connectors for connecting each of the plurality of sockets to a transmission line for delivering signals to each of the sockets; and
first and second output connectors disposed on the second side of the single backplane, the first and second output connectors electrically connected to each of the plurality of sockets by the conductive traces disposed within the single backplane, wherein the first and second output connectors are adapted to plugin to first and second output mating connectors for connecting each of the plurality of sockets to a transmission line for receiving signals from each of the sockets.

28. The housing of claim 27, wherein the case comprises a plurality of cases.

29. The housing of claim 27, wherein the case is disposed in a compartment of the housing.

30. The housing of claim 27, wherein the single backplane is disposed in a compartment of the housing.

31. The housing of claim 27, wherein each of the plurality of circuit cards comprises outside plant electronics.

32. The housing of claim 31, wherein the outside plant electronics is selected from the group consisting of an optical-to-electrical converter, a switching circuit, and an alarm circuit.

33. The housing of claim 27, wherein each of the plurality of circuit cards is a repeater.

34. The housing of claim 27, wherein the single backplane comprises an optical-to-electrical converter.

35. A housing for containing a plurality of circuit cards comprising:
at least two first compartments;
at least two cases respectively disposed within the at least two first compartments, each of the at least two cases comprising a plurality of slots, each of the plurality of slots adapted to respectively receive each of the plurality of circuit cards therein;
a second compartment;
a single backplane disposed within the second compartment, the single backplane comprising a plurality of sockets disposed thereon, each of the plurality of sockets respectively aligned with each of the slots of the at least two cases for respectively receiving each of the plurality of circuit cards therein;
first and second input connectors disposed on a second side of the single backplane, the first and second input connectors electrically connected to each of the plurality of sockets by conductive traces disposed within the single backplane, wherein the first and second input connectors are adapted to plug into first and second input mating connectors for connecting each of the plurality of sockets to a transmission line for delivering signals to each of the sockets; and
first and second output connectors disposed on the second side of the single backplane, the first and second output connectors electrically connected to each of the plurality of sockets by the conductive traces disposed within the single backplane, wherein the first and second output connectors are adapted to plug into first and second output mating connectors for connecting each of the plurality of sockets to a transmission line for receiving signals from each of the sockets.

36. The housing of claim 35, further comprising at least two first covers adapted to respectively close apertures of the at least two first compartments.

37. The housing of claim 35, further comprising a cover adapted to close an aperture of the second compartment.

38. The housing of claim 35, wherein the single backplane comprises an optical-to-electrical converter.

39. The housing of claim 35, wherein each of the plurality of circuit cards comprises outside plant electronics.

40. The housing of claim 39, wherein the outside plant electronics is selected from the group consisting of an optical-to-electrical converter, a switching circuit, and an alarm circuit.

41. The housing of claim 35, wherein each of the plurality of circuit cards is a repeater.

42. A method for manufacturing a single backplane for an 819-type repeater housing, the method comprising:
disposing a plurality of sockets on a first side of the single backplane;
disposing a connector on a second side of the single backplane, wherein the connector is adapted to plug into a mating connector for connecting each of the sockets to input and output transmission lines; and
electrically connecting the connector to each of the plurality of sockets using conductive traces disposed in the single backplane.

43. The method of claim 42, wherein disposing the connector on the single backplane comprises disposing an input and an output connector on the single backplane.

44. The method of claim 42, further comprising disposing the conductive traces within the single backplane.

45. A method for manufacturing a single backplane for an 819-type repeater housing, the method comprising:
disposing a plurality of sockets on a first side of the single backplane;
disposing first and second input connectors on a second side of the single backplane;
electrically connecting the first and second input connectors to each of the plurality of sockets using conductive traces disposed in the single backplane, wherein the first and second input connectors are adapted to plug into first and second input mating connectors for connecting each of the plurality of sockets to a transmission line for delivering signals to each of the sockets;
disposing first and second output connectors on the second side of the single backplane, wherein the first and second output connectors are adapted to plug into first and second output mating connectors for connecting each of the plurality of sockets to a transmission line for receiving signals from each of the sockets; and
electrically connecting the first and second output connectors to each of the plurality of sockets using the conductive traces disposed in the single backplane.

46. The method of claim 45, further comprising disposing the conductive traces within the single backplane.

47. A method for connecting a plurality of repeaters to a transmission line, the method comprising:
respectively inserting each of a plurality of repeaters into each of a plurality of sockets disposed on a first side of a single backplane located in an 819-type repeater housing; and
plugging a mating connector into a connector disposed on a second side of the single backplane to connect each of the plurality of repeaters to the transmission line, wherein the connector is electrically connected to each of the plurality of sockets by conductive traces disposed within the single backplane.

48. The method of claim 47, wherein respectively inserting each of the plurality of repeaters comprises respectively inserting each of the plurality of repeaters into each of a plurality of slots within the 819-type repeater housing, each of the plurality of slots respectively aligned with each of the plurality of sockets.

49. The method of claim 47, wherein respectively inserting each of the plurality of repeaters comprises respectively inserting each of the plurality of repeaters into each of a plurality of slots disposed within a case that is disposed within the 819-type repeater housing, each of the plurality of slots respectively aligned with each of the plurality of sockets.

50. A method for connecting a plurality of repeaters to a transmission line, the method comprising:
respectively inserting each of a plurality of repeaters into each of a plurality of sockets disposed on a first side of a single backplane located in an 819-type repeater housing;
respectively plugging first and second input mating connectors into first and second input connectors disposed on the second side of the single backplane to connect each of the plurality of repeaters to an input line of the transmission line, wherein the first and second input connectors are electrically connected to each of the plurality of sockets by conductive traces disposed within the single backplane; and
respectively plugging first and second output mating connectors into first and second output connectors disposed on a second side of the single backplane to connect each of the plurality of repeaters to an output line of the transmission line, wherein the first and second output connectors are electrically connected to each of the plurality of sockets by the conductive traces disposed within the single backplane.

51. The method of claim 50, wherein respectively inserting each of the plurality of repeaters comprises respectively inserting each of the plurality of repeaters into each of a plurality of slots within the 819-type repeater housing, each of the plurality of slots respectively aligned with each of the plurality of sockets.

52. The method of claim 50, wherein respectively inserting each of the plurality of repeaters comprises respectively inserting each of the plurality of repeaters into each of a plurality of slots disposed within a case that is disposed within the 819-type repeater housing, each of the plurality of slots respectively aligned with each of the plurality of sockets.

53. A method for processing a plurality of signals comprising:
receiving the plurality signals at a connector, wherein the connector is disposed on a first side of a single backplane disposed within an 819-type repeater housing;
respectively conveying each of the plurality of signals to each of a plurality of sockets using conductive traces disposed within the single backplane, wherein each of the plurality of sockets is disposed on a second side of the single backplane;
respectively conveying each of the plurality of signals from each of the plurality of sockets to each of a plurality of repeaters respectively coupled to each of the plurality of sockets; and
respectively processing each of the plurality of signals at each of the plurality of repeaters.

54. The method of claim 53, further comprising respectively conveying each of a plurality of processed signals from each of the plurality of repeaters to each of the plurality of sockets.

55. The method of claim 54, further comprising conveying each of the plurality of processed signals from each of the plurality of sockets to the connector via the conductive traces.

56. The method of claim 55, further comprising conveying the plurality of processed signals from the connector to a mating connector plugged into the connector.

57. The method of claim 53, wherein respectively processing each of the plurality of signals comprises respectively amplifying each of the plurality of signals.

58. The method of claim 53, wherein receiving the plurality signals at a connector comprises receiving the plurality signals from a mating connector plugged into the connector.

59. A method for processing a plurality of first and second signals comprising:
receiving the plurality of first signals at a first connector, wherein the first connector is disposed on a first side of a single backplane disposed within an 819-type repeater housing;
receiving the plurality of second signals at a second connector, wherein the second connector is disposed on the first side of the single backplane;
respectively conveying each of the plurality of first signals to each of a plurality of sockets using conductive traces disposed within the single backplane, wherein the plurality of sockets is disposed on a second side of the single backplane;
respectively conveying each of the plurality of second signals to each of the plurality of sockets using the conductive traces disposed within the single backplane;
respectively conveying each of the plurality of first and second signals from each of the plurality of sockets to each of a plurality of repeaters respectively coupled to each of the plurality of sockets;
respectively processing each of the plurality of first and second signals at each of the plurality of repeaters;
respectively conveying each of a plurality of processed first and second signals from each of the plurality of repeaters to each of the plurality of sockets; and
respectively conveying each of the plurality of processed first and second signals from each of the plurality of sockets to third and fourth connectors via the conductive traces, wherein the third and fourth connectors are disposed on the second side of the single backplane.

60. The method of claim 59, wherein respectively processing each of the plurality of first and second signals comprises respectively amplifying each of the plurality of first and second signals.

61. The method of claim 59, wherein receiving the plurality of first signals at the first connector comprises receiving the plurality of first signals from a mating connector plugged into the first connector.

62. The method of claim 59, wherein receiving the plurality of second signals at the second connector comprises receiving the plurality of second signals from a mating connector plugged into the second connector.

63. The method of claim 59, further comprising respectively conveying the plurality of processed first and second signals to first and second mating connectors respectively plugged into the third and fourth connectors.

64. A single backplane for an optical network unit comprising:
a plurality of sockets disposed on a first side of the backplane, each of the plurality of sockets adapted to receive a circuit card having an optical-to-electrical signal converter; and
a connector disposed on a second side of the backplane and electrically connected to each of the plurality of sockets by conductive traces disposed within the backplane, wherein the connector is adapted to plug into a mating connector for connecting each of the sockets to input and output transmission lines.

65. The backplane of claim 64, wherein the backplane is disposed in a shell.

66. The backplane of claim 64, wherein each of the plurality of sockets comprises a slot for receiving a plug of the circuit card.

67. The backplane of claim 64, wherein the connector comprises an input and output connector.

68. The backplane of claim 64, further comprising a tie disposed on the connector for wrapping around the mating connector to secure the mating connector to the connector when the mating connector plugs into the connector.

69. A single backplane for an optical network unit comprising:
a plurality of sockets disposed on a first side of the backplane, each of the plurality of sockets having a slot adapted to receive a circuit card having an optical-to-electrical signal converter;
first and second input connectors disposed on a second side of the backplane, the first and second input connectors electrically connected to each of the plurality of sockets by conductive traces disposed within the backplane, wherein the first and second input connectors are adapted to respectively plug into first and second input mating connectors for connecting each of the plurality of sockets to a transmission line for delivering signals to each of the sockets; and
first and second output connectors disposed on the second side of the backplane, the first and second output connectors electrically connected to each of the plurality of sockets by the conductive traces disposed within the backplane, wherein the first and second output connectors are adapted to respectively plug into first and second output mating connectors for connecting each of the plurality of sockets to a transmission line for receiving signals from each of the sockets.

70. The backplane of claim 69, wherein the backplane is disposed in a shell.

71. The backplane of claim 69, further comprising a tie disposed on each of the first and second input connectors and on each of the first and second output connectors for wrapping around each of the first and second input mating connectors and each of the first and second output mating connectors to respectively secure each of the first and second input mating connectors to each of the first and second input connectors when each of the first and second input mating connectors respectively plugs into each of the first and second input connectors and to respectively secure each of the first and second output mating connectors to each of the first and second output connectors when each of the first and second output mating connectors respectively plugs into each of the first and second output connectors.
